(19) United States
(12) Patent Application Publication
(10) Pub. No.: US 2010/0182748 A1
(43) Pub. Date: Jul. 22, 2010

(54) DUST-PROOFING METHOD FOR AN ELECTRONIC DEVICE, AND THE ELECTRONIC DEVICE

(76) Inventor: Chia-Feng HUANG, Taipei Hsien (TW)

Correspondence Address: NIXON & VANDERHYE, PC, 901 NORTH GLEBE ROAD, 11TH FLOOR, ARLINGTON, VA, 22203, US

(21) Appl. No.: 12/620,983

(22) Filed: Nov. 18, 2009

(30) Foreign Application Priority Data
Jan. 21, 2009 (TW) 098102232

(51) Int. Cl. H05K 7/20

(52) U.S. Cl. 361/690

(57) ABSTRACT

A dust-proofing method is for use in an electronic device having a housing, a heat-generating component, and a dust-proofing mechanism. The housing includes an air vent. The dust-proofing mechanism includes a shielding plate for shielding or opening the air vent, and an actuating unit for driving movement of the shielding plate. The dust-proofing method includes: causing the actuating unit to drive movement of the shielding plate to open the air vent upon detecting that the temperature of the heat-generating component has risen to a first preset temperature; and causing the actuating unit to drive movement of the shielding plate to shield the air vent upon detecting that the temperature of the heat-generating component has dropped to a second preset temperature lower than the first preset temperature. Thus, dust accumulation in the electronic device can be effectively reduced, and heat dissipation efficiency can be enhanced.

### CROSS-REFERENCE TO RELATED APPLICATION

This application claims priority of Taiwanese Application No. 098102232, filed on Jan. 21, 2009.

### BACKGROUND OF THE INVENTION

1. Field of the Invention

The invention relates to a dust-proofing method for an electronic device and to the electronic device, more particularly to a dust-proofing method for an electronic device which controls opening and closing of an air vent in response to changes in the temperature of a heat-generating component, and to the electronic device.

2. Description of the Related Art

Since current notebook computers are designed to be compact in size and lightweight, how to ensure that a heat-dissipating module has a satisfactory heat-dissipating efficiency with respect to a central processing unit (CPU) under the constraint of limited space is an important issue.

Many of the causes for poor heat dissipation are associated with accumulation of dust on impellers of the fan of the heat-dissipating module, or accumulation of dust on heat-dissipating fins of the heat-dissipating module. One way to alleviate the problem of dust accumulation is that, instead of arranging an air vent immediately below the fan of the heat-dissipating module, the air vent is provided at other positions of the housing of the notebook computer to introduce air into the housing. Although such a method can slow down the accumulation of dust, with the central processing unit operating under heavier and heavier loads, the working temperature of the central processing unit becomes higher and higher. Given that the air intake area provided by the air vent is fixed and that the amount of air intake hence cannot be increased to enhance heat dissipation efficiency, to devise a design that can effectively reduce dust accumulation and that can timely increase the amount of air intake with the rise in the working temperature of the central processing unit is the subject of improvement of this invention.

### SUMMARY OF THE INVENTION

Therefore, the primary object of the present invention is to provide a dust-proofing method for an electronic device, which can effectively reduce dust accumulation and enhance heat dissipation efficiency by controlling the opening or closing of an air vent of the electronic device.

Another object of the present invention is to provide an electronic device capable of effectively reducing dust accumulation and enhancing heat dissipation efficiency by controlling the opening or closing of an air vent of the electronic device.

The objects of the present invention and the solution to the problems associated with the aforementioned prior art are realized using the following technical means. The dust-proofing method according to the present invention is used in an electronic device including a housing, and a heat-generating component and a dust-proofing mechanism provided in the housing. The housing includes an air vent. The dust-proofing mechanism includes a shielding plate for shielding or opening the air vent, and an actuating unit for driving movement of the shielding plate. The dust-proofing method comprises:

(A) causing the actuating unit to drive movement of the shielding plate to open the air vent upon detecting that the temperature of the heat-generating component has risen to a first preset temperature; and

(B) causing the actuating unit to drive movement of the shielding plate to shield the air vent upon detecting that the temperature of the heat-generating component has dropped to a second preset temperature lower than the first preset temperature.

In the aforementioned dust-proofing method, the heat-generating component is a central processing unit. The first preset temperature is 80° C. The second preset temperature is 65° C. The first and second preset temperatures may be adjusted depending on the kind of venue the electronic device is used and design requirements.

The electronic device of the present invention includes a housing, a heat-generating component, and a dust-proofing mechanism.

The housing includes a receiving space and an air vent in fluid communication with the receiving space. The heat-generating component is provided in the receiving space. The dust-proofing mechanism includes a temperature detecting element for detecting the temperature of the heat-generating component, a shielding plate for shielding or opening the air vent, and an actuating unit for driving the shielding plate to move relative to the housing. The actuating unit drives movement of the shielding plate to open the air vent when the temperature detecting element detects that the temperature of the heat-generating component has risen to a first preset temperature. The actuating unit drives movement of the shielding plate to shield the air vent when the temperature detecting element detects that the temperature of the heat-generating component has dropped to a second preset temperature lower than the first preset temperature.

In the aforementioned electronic device, the dust-proofing mechanism further includes a controller connected electrically to the temperature detecting element for receiving temperature detect signals therefrom and for controlling operation of the actuating unit.

In the aforementioned electronic device, the actuating unit includes a drive circuit, a motor, and a linkage connected to the shielding plate and the motor. The drive circuit drives the motor to operate to enable the motor to drive movement of the linkage so as to bring the shielding plate to move between an open position to open the air vent and a shielding position to shield the air vent.

In the aforementioned electronic device, the motor has a stator, and a rotor rotatable relative to the stator and connected pivotally to the linkage. The rotor includes a ring-shaped magnet. The drive circuit supplies an electric current to the stator to enable the stator to generate a magnetic field so as to enable the magnet of the rotor to rotate relative to the stator by virtue of a magnetic force created by the magnetic field.

In the aforementioned electronic device, the actuating unit further includes a position sensing element, which is controllable by the controller to sense positions of magnetic poles of the magnet so as to cause the drive circuit to supply an electric current to the stator.

In the aforementioned electronic device, the housing further includes two elongated guide rails provided respectively at two opposite sides of the air vent and connected slidably to the shielding plate.

In the aforementioned electronic device, the heat-generating component is a central processing unit. The first preset temperature is 80° C., and the second preset temperature is 65° C.

In the dust-proofing method for the electronic device according to this invention, by virtue of the configuration of the dust-proofing mechanism, the shielding plate will move from the shielding position to the open position when the working temperature of the heat-generating component rises to the first preset temperature so as to increase the amount of air intake for enhancing heat dissipation efficiency, and will move from the open position to the shielding position when the temperature of the heat-generating component drops from the first preset temperature or a temperature above the first preset temperature to the second preset temperature, thereby preventing entry of dust into the receiving space through the air vent.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a preferred embodiment of an electronic device according to the invention;

FIG. 2 is a fragmentary perspective view of the electronic device of FIG. 1;

FIG. 3 is a fragmentary schematic view of the preferred embodiment of the electronic device according to the invention, illustrating a shielding plate at a shielding position;

FIG. 4 is a schematic view of the preferred embodiment of the electronic device according to the invention, illustrating the arrangement relationship between a stator and a rotor of a motor when the shielding plate is at the shielding position;

FIG. 5 is a block diagram to illustrate a dust-proofing mechanism of the preferred embodiment of the electronic device according to the invention;

FIG. 6 is a flowchart to illustrate a preferred embodiment of a dust-proofing method according to the invention;

FIG. 7 is a fragmentary schematic view of the preferred embodiment of the electronic device according to the invention, illustrating how the motor drives movement of a linkage and the shielding plate;

FIG. 8 is a view similar to FIG. 4, illustrating how the rotor rotates relative to the stator;

FIG. 9 is a fragmentary schematic view of the preferred embodiment of the electronic device according to the invention, illustrating the shielding plate at an open position;

FIG. 10 is a schematic view of the preferred embodiment of the electronic device according to the invention, illustrating the arrangement relationship between the stator and the rotor of the motor when the shielding plate is at the open position; and

FIG. 11 is a view similar to FIG. 10, illustrating how the rotor rotates relative to the stator.

### DETAILED DESCRIPTION OF THE PREFERRED EMBODIMENT

Through a description of the preferred embodiment, the technical means employed by the present invention to achieve the intended objects and advantageous effects of the invention can be better appreciated. It is noted that the accompanying drawings are for illustration and reference only, and are not intended to limit the scope of protection sought for the present invention.

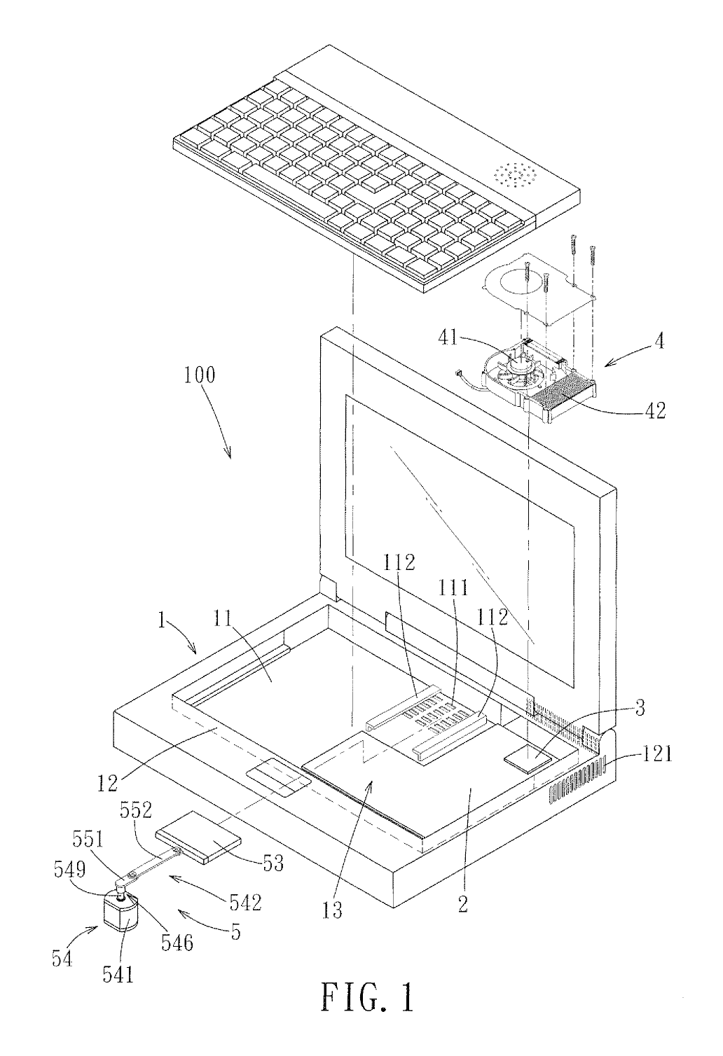

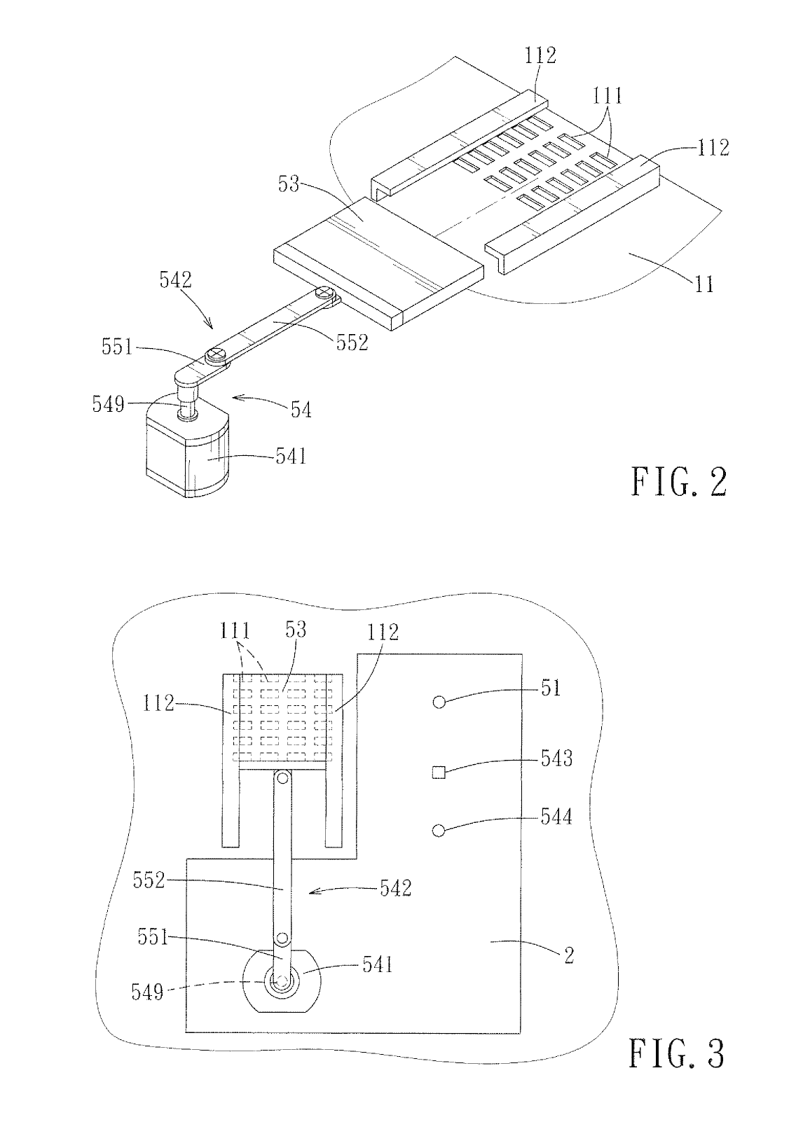

The preferred embodiment of a dust-proofing method according to the present invention is for use in an electronic device 100 as shown in FIGS. 1 and 2. The electronic device 100 includes a housing 1, a motherboard 2, a heat-generating component 3, a heat-dissipating module 4, and a dust-proofing mechanism 5. In this embodiment, the electronic device 100 is a notebook computer, and the heat-generating component 3 is a central processing unit disposed on the motherboard 2. Certainly, the electronic device 100 may be a desktop computer or any other type of computer, and the heat-generating component 3 may be a chip or any other electronic component that will generate a large amount of heat during operation.

The housing 1 includes a bottom plate 11, a surrounding wall 12 connected to and surrounding the bottom plate 11, and a receiving space 13 cooperatively defined by the bottom plate 11 and the surrounding wall 12. The motherboard 2, the heat-dissipating module 4, and the dust-proofing mechanism 5 are provided in the receiving space 13. The bottom plate 11 is provided with a plurality of air vents 111 in fluid communication with the receiving space 13, and two elongated guide rails 112 located respectively at opposite left and right sides of the plurality of air vents 111. The air vents 111 are located below a fan 41 of the heat-dissipating module 4. Heat-dissipating fins 42 of the heat-dissipating module 4 are in abutment with the heat-generating component 3. Thus, the outside air can be drawn into the housing 1 by the fan 41 of the heat-dissipating module through the air vents 111 to blow toward the heat-dissipating fins 42, so as to dissipate the heat transferred to the heat-dissipating fins 42 by the heat-generating component 3 when the latter operates via air outlets 121 in the surrounding wall 12.

Referring to FIGS. 2, 3, 4, and 5, the dust-proofing mechanism 5 includes a temperature detecting element 51, a controller 52, a shielding plate 53, and an actuating unit 54. The temperature detecting element 51 is provided on the motherboard 2 for detecting the temperature of the heat-generating component 3 (see FIG. 1), and correspondingly generates different temperature detect signals in response to changes in the temperature of the heat-generating component 3 when the heat-generating component 3 operates. The controller 52 is an embedded controller connected electrically to the temperature detecting element 51 for receiving the temperature detect signals from, the temperature detecting element 51. The shielding plate 53 is connected slidably to the two elongated guide rails 112, and is driven by the actuating unit 54 to shield or open the air vents 111. When the electronic device 100 is powered off, the shielding plate 53 is in a shielding position where it shields the air vents 111, as shown in FIG. 3. The actuating unit 54 is controlled by the controller 52 to drive movement of the shielding plate 53. The actuating unit 54 includes a motor 541, a linkage 542, a position sensing element 543, and a drive circuit 544. The motor 541 is provided on the motherboard 2, and has a stator 545 and a rotor 546 rotatable relative to the stator 545. The stator 545 includes two coils 547, 548 that are located at opposite sides thereof. The rotor 546 includes a rotating shaft 549, and a ring-shaped magnet 550 surrounding the coils 547, 548 of the stator 545. The linkage 542 has a first link portion 551 and a second link portion 552. The first link portion 551 has one end pivoted to the rotating shaft 549 of the rotor 546. The second link portion 552 has two ends pivoted respectively to the other end of the first link portion 551 and the shielding plate 53, whereby rotation of the rotating shaft 549 of the motor 541 can drive movement of the linkage 542 and the shielding plate 53.

The position sensing element 543 is provided on the motherboard 2 for sensing positions of a north pole 553 and a south pole 554 of the magnet 550 of the rotor 546. The position sensing element 543 transmits sensing signals to the drive circuit 544 to cause the drive circuit 544 to supply an electric current to the coils 547, 548 of the stator 545 so that the coils 547, 548 generate a magnetic field, whereby the magnet 550 of the rotor 546 is capable of rotation relative to the stator 545 by virtue of the magnetic force created by the magnetic field thus generated.

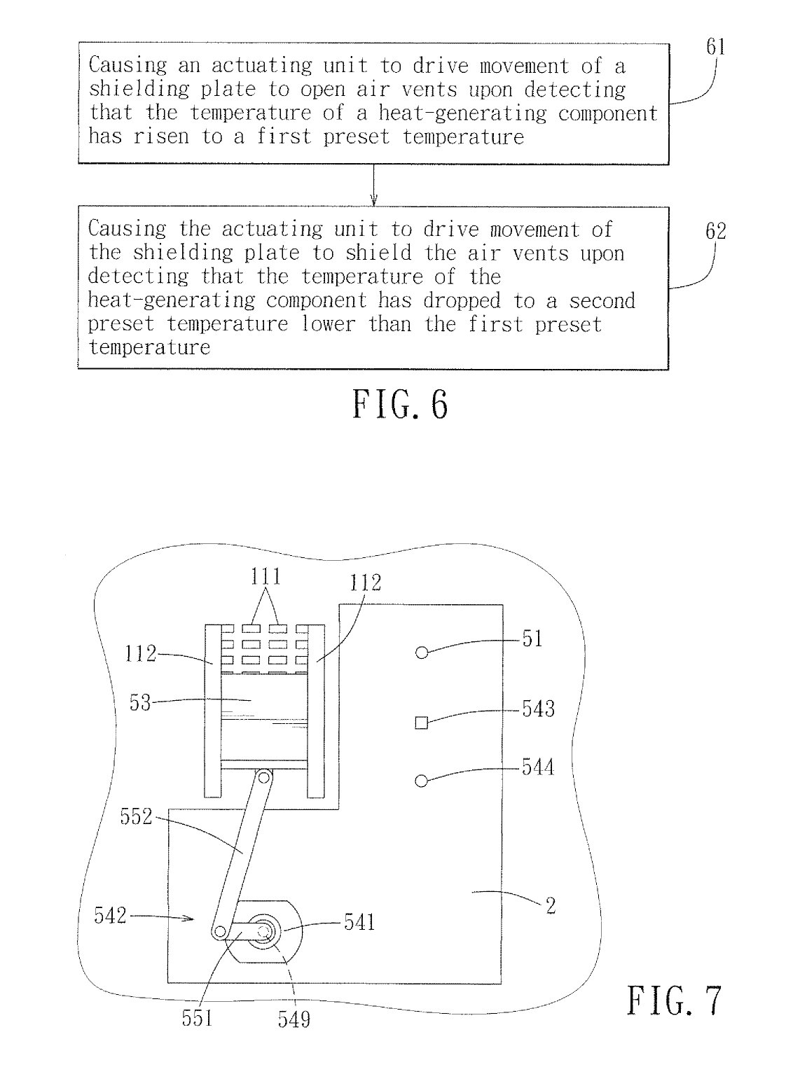

The dust-proofing method for the electronic device 100 according to this invention will be described in detail hereinbelow with reference to FIGS. 3, 4, 5, and 6. FIG. 6 is a flowchart illustrating the dust-proofing method for the electronic device 100.

In step 61, after the electronic device 100 is powered on, the temperature detecting element 51 detects the temperature of the heat-generating component 3, and transmits a temperature detect signal to the controller 52. When the temperature detecting element 51 detects that the temperature of the heat-generating component 3 has risen to a first preset temperature, which is, e.g., set to be 80° C. in this embodiment, the controller 52 will send a control voltage to the fan 41 of the heat-dissipating module 4 and the position sensing element 543 to cause the fan 41 to rotate at an increased speed and to drive the position sensing element 543 to sense the positions of the north pole 553 and the south pole 554 of the magnet 550 of the rotor 546. The position sensing element 543 will transmit the sensing signals to the drive circuit 544 so that the drive circuit 544 can supply an electric current to the coils 547, 548 of the stator 545 depending on the positions of the north pole 553 and the south pole 554 of the magnet 550, thereby enabling the coils 547, 548 to create a magnetic field which repels the magnet 550.

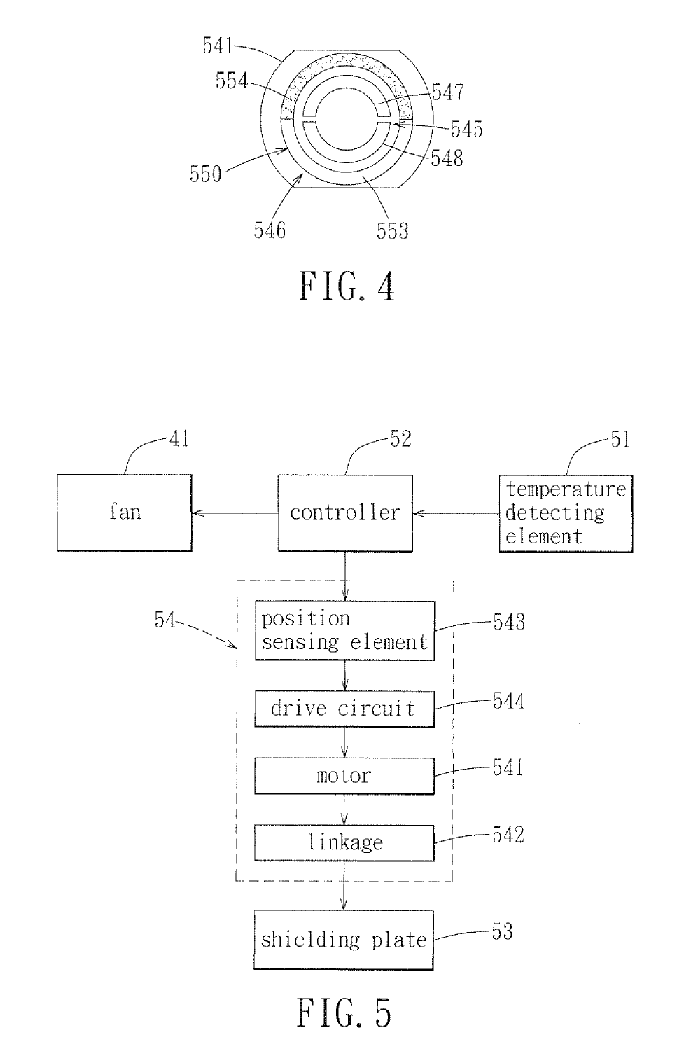

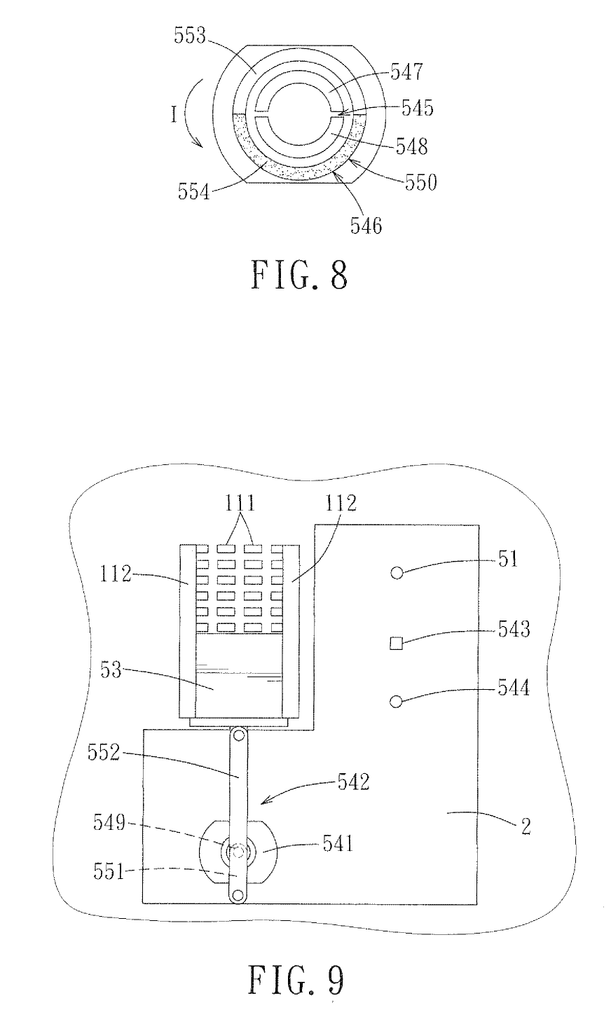

Referring to FIGS. 3, 4, 7, and 8, after an electric current is supplied to the coils 547, 548 of the stator 545 by the drive circuit 544 (see FIG. 5), the coil 547 (see FIG. 4) will generate a south pole, whereas the coil 548 (see FIG. 4) will generate a north pole. Under the principle that like poles repel and unlike poles attract, the magnet 550 of the rotor 546 will rotate relative to the stator 545 along a direction indicated by the arrow (I) (see FIG. 8) as a result of the magnetic force thus generated so as to drive movement of the linkage 542 and the shielding plate 53. When the north pole 553 and the south pole 554 of the magnet 550 of the rotor 546 have rotated 180 degrees, as shown in FIG. 8, and are respectively attracted to the coils 547, 548, the shielding plate 53 moves along an extension direction of the elongated guide rails 112 from the shielding position where the shielding plate 53 shields the air vents 111, as shown in FIG. 3, to the open position where the air vents 111 are opened, as shown in FIG. 9. Thus, the fan 41 of the heat-dissipating module 4 can not only draw in the outside air through air vents (not shown) arranged in other positions of the housing 1, it can also draw in the outside air directly through the air vents 111 to blow toward the heat-dissipating fins 42 (see FIG. 1), so that the heat transferred to the heat-dissipating fins 42 by the heat-generating component 3 can be dissipated through the air outlets 121.

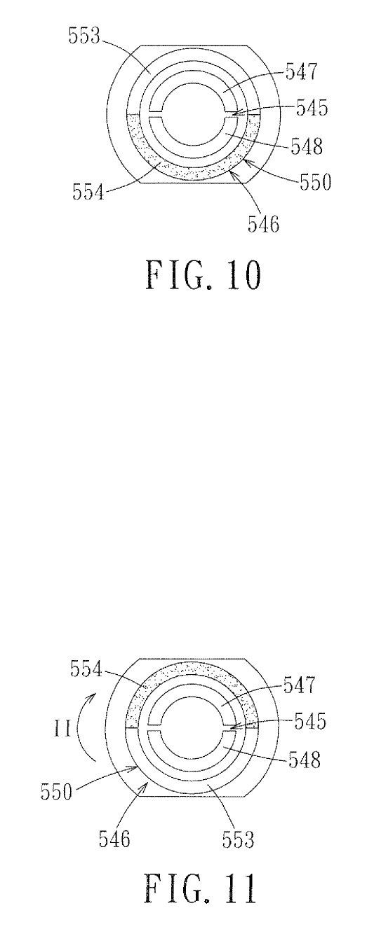

Referring to FIGS. 5, 6, 9, and 10, in step 62, when the temperature detecting element 51 detects that the temperature of the heat-generating component 3 has dropped from the first preset temperature or a temperature above the first preset temperature to a second preset temperature (which is, e.g., set to 65°C. in this embodiment) lower than the first preset temperature, the controller 52 will send a control voltage to the fan 41 of the heat-dissipating module 4 and the position sensing element 543 to cause the fan 41 to rotate at a reduced speed, and to simultaneously drive the position sensing element 543 to sense the positions of the north pole 553 and the south pole 554 of the magnet 550 of the rotor 546 and to transmit the sensing signals to the drive circuit 544, so that the drive circuit 544 can supply an electric current to the coils 547, 548 of the stator 545 depending on the positions of the north pole 553 and the south pole 554 of the magnet 550, thereby enabling the coils 547, 548 to generate a magnetic field which repels the magnet 550. The coil 547 (see FIG. 10) will generate a north pole, whereas the coil 548 (see FIG. 10) will generate a south pole, so that the rotor 546 is brought to rotate relative to the stator 545 along a direction indicated by arrow (II) (see FIG. 11) by the magnetic force thus generated so as to drive movement of the linkage 542 and the shielding plate 53. When the north pole 553 and the south pole 554 of the magnet 550 of the rotor 546 have rotated 180 degrees, as shown in FIG. 11, and are respectively attracted to the coils 548, 547, the shielding plate 53 moves along the extension direction of the elongated guide rails 112 from the open position shown in FIG. 9 to the shielding position shown in FIG. 3. Thus, entry of dust into the receiving space 13 through the air vents 111 can be prevented.

It is particularly noted that, except in circumstances where the user uses the electronic device 100 to play games or execute simulation analysis software, or the electronic device 100 is used in a hot environment so that the temperature of the heat-generating component rises above the first preset temperature due to increased workload of the heat-generating component 3 or environmental temperature influences, under normal use conditions, the working temperature of the heat-generating component 3 is generally below the first preset temperature. Therefore, the shielding plate 53 is normally disposed at the shielding position to shield the air vents 111, thereby effectively reducing the amount of dust entering through the air vents 111 and accumulating on the fan 41 and the heat-dissipating fins 42 of the heat-dissipating module 4. The actuating unit 54 will drive the shielding plate 53 to move to the open position to increase the amount of air intake for enhancing the efficiency of dissipating the heat of the heat-generating component 3 only when the temperature of the heat-generating component 3 has risen to the first preset temperature. The first and second preset temperatures may be adjusted depending on the kind of venue the electronic device 100 is used and design requirements, and should not be limited to the temperatures disclosed in this embodiment.

In addition, although the operation of the dust-proofing mechanism 5 is illustrated to be in relation to changes in the temperature of the heat-generating component 3 from a power-off state to a state in which the temperature of the heat-generating component 3 has risen to the first preset temperature and in relation to the drop in temperature from the first preset temperature or a temperature above the first preset temperature to the second preset temperature, the working temperature of the heat-generating component 3 will fluctuate during actual operation. Therefore, the shielding plate 53 of the dust-proofing mechanism 5 will continuously move between the shielding position and the open position. Furthermore, if the temperature of the heat-generating component 3 is maintained at a temperature below the first preset temperature after powering on the electronic device 100, the shielding plate 53 will be maintained at the shielding position. The shielding plate 53 will move to the open position only when the temperature of the heat-generating component 3 rises to the first preset temperature.

In sum, in the dust-proofing method for the electronic device 100 according to this invention, by virtue of the configuration of the dust-proofing mechanism 5, the shielding plate 53 will move from the shielding position to the open position when the working temperature of the heat-generating component rises to the first preset temperature so as to increase the amount of air intake for enhancing heat dissipation efficiency, and will move. from the open position to the shielding position when the temperature of the heat-generating component 3 drops from the first preset temperature or a temperature above the first preset temperature to the second preset temperature, thereby preventing entry of dust into the receiving space 13 through the air vents 111.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A dust-proofing method for an electronic device including a housing, and a heat-generating component and a dust-proofing mechanism disposed in the housing, the housing including an air vent, the dust-proofing mechanism including a shielding plate for shielding or opening the air vent, and an actuating unit for driving movement of the shielding plate, said dust-proofing method comprising:
(A) causing the actuating unit to drive movement of the shielding plate to open the air vent upon detecting that the temperature of the heat-generating component has risen to a first preset temperature; and
(B) causing the actuating unit to drive movement of the shielding plate to shield the air vent upon detecting that the temperature of the heat-generating component has dropped to a second preset temperature lower than the first preset temperature.

2. The dust-proofing method of claim 1, wherein the heat-generating component is a central processing unit.

3. The dust-proofing method of claim 2, wherein the first preset temperature 80° C.

4. The dust-proofing method of claim 2, wherein the second preset temperature is 65° C.

5. An electronic device, comprising:
a housing including a receiving space and an air vent in fluid communication with the receiving space;
a heat-generating component provided in the receiving space; and
a dust-proofing mechanism including a temperature detecting element for detecting temperature of said heat-generating component, a shielding plate for shielding or opening said air vent, and an actuating unit for driving said shielding plate to move relative to said housing, said actuating unit driving movement of said shielding plate to open said air vent when said temperature detecting element detects that the temperature of said heat-generating component has risen to a first preset temperature, said actuating unit driving movement of said shielding plate to shield said air vent when said temperature detecting element detects that the temperature of said heat-generating component has dropped to a second preset temperature lower than the first preset temperature.

6. The electronic device of claim 5, wherein said dust-proofing mechanism further includes a controller connected electrically to said temperature detecting element for receiving temperature detect signals therefrom and for controlling operation of said actuating unit.

7. The electronic device of claim 6, wherein said actuating unit includes a drive circuit, a motor, and a linkage connected to said shielding plate and said motor, said drive circuit driving said motor to operate to enable said motor to drive movement of said linkage so as to bring said shielding plate to move between an open position to open said air vent and a shielding position to shield said air vent.

8. The electronic device of claim 7, wherein said motor has a stator, and a rotor rotatable relative to said stator and connected pivotally to said linkage, said rotor including a ring-shaped magnet, said drive circuit supplying an electric current to said stator to enable said stator to generate a magnetic field so as to enable said magnet of said rotor to rotate relative to said stator by virtue of a magnetic force created by the magnetic field.

9. The electronic device of claim 8, wherein said actuating unit further includes a position sensing element, which is controllable by said controller to sense positions of magnetic poles of said magnet so as to cause said drive circuit to supply an electric current to said stator.

10. The electronic device of claim 7, wherein said housing further includes two elongated guide rails provided respectively at two opposite sides of said air vent and connected slidably to said shielding plate.

11. The electronic device of claim 5, wherein said heat-generating component is a central processing unit.

12. The electronic device of claim 11, wherein the first preset temperature is 80° C.

13. The electronic device of claim. 11, wherein the second preset temperature is 65° C.
